(19) United States
(12) Patent Application Publication
(10) Pub. No.: US 2006/0073276 A1
(43) Pub. Date: Apr. 6, 2006

(54) Multi-zone atomic layer deposition apparatus and method

(76) Inventor: Eric Antonissen, Redwood City, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 11/239,966

(22) Filed: Sep. 30, 2005

Related U.S. Application Data
(60) Provisional application No. 60/616,167, filed on Oct. 4, 2004.

(51) Int. Cl. C23C 16/00

(52) U.S. Cl. 427/248.1; 118/715

(57) ABSTRACT

Method and apparatus for producing a thin film on a substrate set in a moving substrate holder is disclosed. Within a deposition chamber, a substrate is moved across a series of dedicated deposition zones and is subjected to repeated surface reactions with at least two different reactants. The reactants are fed into the dedicated deposition zones from a gas supply system that may include high speed valves that are timed to coordinate with the passage of the substrate so as to inject reactive gases repeatedly into the deposition zones. The dedicated deposition zones are separated by dedicated exhaust zones that direct each reactive gas along separate paths so as to minimize or eliminate mixing of different reactive species in the exhaust thus decreasing deposition within the exhaust system.

### CROSS-REFERENCE TO RELATED APPLICATION

This application claims priority under 35 U.S.C. § 119(e) to U.S. Provisional Patent Application Ser. No. 60/616,167, “Multi-Zone Atomic Layer Deposition Apparatus and Method,” filed Oct. 4, 2004, which is incorporated herein by reference in its entirety.

### BACKGROUND OF THE INVENTION

1. Field of the Invention

This invention relates generally to thin film deposition apparatus and methods. More particularly, it relates to atomic layer deposition apparatus and methods.

2. Description of the Related Art

Thin films are generally deposited on semiconductor substrates by a physical vapor deposition (PVD) process such as sputtering or by a chemical vapor deposition (CVD) process. However, when the surface of the substrate is strongly stepped (e.g., high aspect ratio structures that are narrow and deep) and the dimension of the opening at the top of the structure is small, as can occur in current day semiconductor designs, a thin film deposited by these PVD and CVD methods tend to have poor step coverage. In addition, CVD methods may employ relatively high temperatures that may be deleterious on the devices being manufactured. Further, some applications such as read-write heads used in magnetic recording systems require precise control of thin film thickness and pin-hole free quality. In addition, as semiconductor device scales are reduced, the thickness of thin films required by the semiconductor device has decreased and better thickness control is required. Accordingly, the PVD and CVD methods tend to be inadequate to properly deposit films, thus resulting in yield loss or, in the extreme, an inability to make a functional device. As semiconductor technology continues to push the dimensional boundaries of these processes, an alternative to both the PVD and CVD processes for various applications is desirable.

Atomic layer deposition (ALD) is a leading candidate to address the problems associated with PVD and CVD methods. In ALD, a thin film of a material is grown essentially one atomic layer at a time by repetition of self-limiting chemical reactions. In the conventional ALD method, the reactants, or precursors as they are called, are separately injected into a reactor that contains a substrate. The precursors react in sequence at the substrate surface to deposit an element or compound of interest. In a typical system, the first precursor adsorbs as a monolayer onto available sites on the substrate surface. The reactor chamber is then purged of the excess first precursor and the second precursor is introduced. The second precursor reacts with the first precursor layer attached at the substrate surface, such that the resulting reaction leaves behind a material of interest deposited conformally on the substrate (i.e., following the surface of the substrate). The excess second precursor and reaction by-products are purged away. The cycle can be repeated beginning with the first precursor that will this time adsorb onto the newly deposited layer. A layer of interest can then be grown to a desired thickness.

However, conventional ALD equipment suffers from numerous drawbacks. For example, U.S. Pat. No. 4,058,430 by Suntola et al., generally concerns an ALD apparatus which involved a rotating disk holding substrates that were passed through different continuously fed reactive gas zones separated by an exhaust zone. This apparatus failed to adequately separate the reactive gases as well as the reactive by-products, resulting in inferior depositions as described in U.S. Pat. No. 4,389,973 by Suntola et al. In this second patent, the initial design was improved by using a single deposition zone with continuous purge flow and a pulsed introduction of precursors. Reactants and by-products were swept in and swept out by the purge gas in a manner that reduces cross-mixing. The purge gas acts as an effective diffusion barrier to cross mixing of precursors in the gas phase. However, in this approach, material is also deposited on the walls of the reactor chamber, which has several drawbacks. For example, it increases the cycle time because an effective purge of the reactor can take several seconds. In addition, inadequate purges can contribute to CVD behavior in the reactor as well as reaction by-products that may cause poor film quality. The exhaust flow can also get mixed downstream resulting in CVD behavior that may occur in the vacuum pump and cause premature pump failure. As a final example, the chamber walls can also become coated, potentially becoming a source of particles as well as impacting the heat transfer characteristics of the chamber.

More recent approaches include synchronously modulated input and output gas flows to increase the throughput by forcing gases in and out more rapidly (U.S. Pat. No. 6,540,838 by Sneh et al.), the introduction of plasma into the reaction chamber to enhance the reactivity of a precursor (U.S. Pat. No. 6,569,501 by Chiang et al.), and the use of a gate valve to throttle the fore line exhaust into different pathways to reduce deleterious CVD deposition into the vacuum pumps (U.S. Pat. No. 6,716,284 by Campbell et al.). However, none of these approaches sufficiently addresses the current throughput requirements of the industry and at the same time provide for a low cost of ownership vis-à-vis waste management, long maintenance intervals, and efficient use of precursors on a flexible platform able to support a wide range of chemistries.

In another approach based on plasma enhancement (U.S. Patent Publication 20040082171 by Shin, Cheol Ho et al.), which is reminiscent of the first apparatus by Suntola et al. (U.S. Pat. No. 4,058,430), a reaction chamber with plasma enhanced capability includes a rotating disk substrate holder with an arrayed gas spray unit mounted on the upper end of the housing above a gas holder with the exhaust occurring along the outer edge of the disk. In this case, a single chamber volume is used for the process such that each precursor has an associated purge gas curtain (diffusion barrier) used for maintaining separation of the precursor species. In this case, there are multiple species (precursor+purge gas) present in a given deposition sub-volume within the ALD chamber. This dilutes the precursor concentration, leading to lower efficiency. In addition, this system also has a common exhaust path leading to potentially high deposition rates within the vacuum pump(s), which tends to foul the pumps. Finally, the use of a gas curtain with the rotating substrate holder, which can effectively act as a mixing element in the chamber, severely limits the rotation rate of the system so that the cycle rate (throughput) may be relatively low.

More recently, U.S. Pat. No. 6,821,563 by Yudovsky concerns a deposition system with a plurality of adjacent gas inlets and vacuum ports along with a rotating substrate holder similar to the early system by Suntola et al. (U.S. Pat. No. 4,058,430). In this system, isolation between precursors is achieved by the active use of purge gases to maintain separation of the respective precursor gases. That is, purge gases are actively introduced into the reactor chamber between the precursor inlets in order to form a diffusion barrier that viscously flows toward the common exhaust path to isolate and remove excess precursor out of the chamber. However, if the system is operated in a non-viscous flow regime, the purge gas would fail to prevent precursor cross-flow as well as backflow in the shared exhaust paths, both resulting in excessive CVD behavior. Another drawback to this approach is that the purge gases dilute the precursors which slows the deposition process, is less efficient in the use of precursors as well as potentially contributing to lower quality films, and the shared vacuum/exhaust line provides a pathway for backstreaming precursors to enter into adjacent inlet zones unless a substantial amount of purge gas pressure/flow is used, i.e., the system is operated in the viscous flow regime. Further, the common exhaust path can become a region of significant CVD deposition which can lead to premature pump failure.

Another recent approach by Sferlazzo (U.S. Patent Publication 20040187784) concerns a system that attempts to have isolated precursor zones by using a combination of internal chamber wall boundaries with zones of continuous flow isolated from other regions using a purge gas and/or moving seals. Further, there is a common area adjacent to all the zones which is pumped to some desired level of vacuum. One drawback with this approach is that the common area will serve as a region of CVD-like deposition because there will be some leakage of the precursors into the common area. Further, again the extensive use of purge gas will dilute the precursors resulting in lower throughput and lower precursor utilization. The use of moving seals can limit rotation rates and contribute to particles as well as being a maintenance issue.

Thus there is a need for an improved ALD system that would preferably have higher throughput, higher cleanliness, higher chemical utilization, improved waste management, and/or better process control.

### SUMMARY OF THE INVENTION

In one aspect, the present invention overcomes the limitations of the prior art by employing a series of dedicated low volume precursor deposition zones separated by dedicated larger volume exhaust zones, in conjunction with a moving substrate holder disposed within a chamber. The internal chamber walls and the substrate holder form a small gap that acts to provide for the passage of a given precursor gas across a substrate in a given dedicated deposition zone but restricts the flow of different precursor(s) and/or reaction by-products from the given deposition zone into another dedicated zone. Typically, the system is not internally leak proof but a high degree of precursor separation is achieved, resulting in a platform that is able to produce high quality ALD films at high deposition rates.

Deposition zones are created when the substrate is moved by the substrate holder into a precursor inlet zone and precursor gas is injected such that it flows across the substrate toward the dedicated larger volume exhaust zones. Because the deposition zone for a given precursor inlet zone is dedicated, i.e., only one precursor is explicitly introduced, there is no longer a need to remove excess precursor from the zone. Because the exhaust zones have large volume, excess precursor and reaction by-products have very low pressure in the exhaust zone as the substrate moves to the deposition zone for the next precursor gas. Very little precursor gas from one precursor region is able to reach another precursor region because of the low precursor/by-products pressure, efficient exhausting, as well as the flow restrictions imposed by the gap, disk hub, etc. This approach eliminates the need for an explicit purge of a precursor from the deposition zone, thus improving the cycle rate. However, purges in between the adjacent exhaust zones can be used to act as an additional diffusion barrier limiting a given precursor flow to within its dedicated deposition and exhaust zone. The use of high speed valves, now commercially available, in supplying timed injections of precursor gases and purge gases improve the overall gas management, cleanliness, and speed of the system. Substrate cleanliness is further enhanced by the fact that pressures typically are maintained below order 1 torr even at the precursor inlet zone such that particle movement does not readily take place. In the case of explicit purges between exhaust zones, higher pressures may be encountered resulting in possible deleterious particle movement onto the substrate if the chamber and/or substrate are inadequately clean.

Various aspects of the invention include the following. The precursor reactants preferably are separated (via the use of dedicated precursor deposition zones) except where they are supposed to react, namely at the surface of the substrate. The use of low volume, dedicated deposition zones leads to efficiency, cleanliness, and speed improvements. The pulsing of gases into the relatively low pressure system limits the amount of gas introduced into the system and the gas moves rapidly to where it needs to be. As a final example, the use of large exhaust volumes with high gas conductance and high pumping rates results in effective removal of excess precursor and reaction by-products.

In one design, the substrate holder has recesses to receive the substrate(s) which allows for maintaining a narrow gap between the internal chamber wall and the substrate holder in the non-recessed regions to limit precursor gas flow between adjacent deposition zones. A deposition zone is formed when a given recess, with a substrate placed therein, is in proximity of a given precursor inlet zone whereby a given precursor gas is injected and is adsorbed onto the substrate. One or more substrates can be placed in individual recesses of the holder and moved through a series of precursor inlet and exhaust zones such that a first precursor is adsorbed onto the substrate surface in a first deposition zone, the excess first precursor is largely removed in a first exhaust zone, and a second precursor reacts with the first adsorbed precursor on the substrate in a second deposition zone so as to leave behind a deposit on the substrate of a desired material, and the excess second precursor and associated by products are removed in a second exhaust zone, and so on. Higher order reaction systems can be accommodated by having a third or fourth, etc., dedicated deposition zone and associated exhaust zones.

The arrangement according to the invention provides significant benefits over conventional ALD devices. For instance, precursor gas distribution onto the substrate occurs in small dedicated deposition zones formed between the precursor inlet zone and the substrate holder. It is desirable to have a small volume deposition zone to reduce excess precursor usage and to reduce the amount of material exhausted. Also, the fact that the deposition zones are dedicated means that only one type of precursor is primarily present such that the deposition zone walls, other than the substrate, are not sinks for the precursor, which again improves precursor utilization. Additionally, the fact that only a small amount of precursor is required to adequately “pressurize” the deposition zone means that excess precursor and by-products can be more easily removed by the associated exhaust zones. This also means that even precursors previously unsuitable or undesirable for ALD because of their very low vapor pressures, could be successfully used because of the very low background pressure and lack of dilution (e.g., no purge gas or carrier gas) in the system as well as the very small deposition volume.

With relatively large volume exhaust zones, there is a large vacuum reservoir with high gas conductance to effectively remove excess precursor and reaction by-products as the substrate moves into a dedicated exhaust zone adjacent to a given precursor inlet zone. Typically, the average pressure in the exhaust manifold or plenum is less than 20 mT and preferably less than 1 mT. A relatively smooth pulse of precursor gas is introduced at the precursor inlet zone with adequate pressure and flow to achieve substrate surface saturation as the substrate moves through the precursor inlet zone. The precursor gas maintains a relatively high pressure over the substrate when limited to the relatively low volume deposition zone. As the pulse and substrate propagate toward the exhaust zone, the gas pressure drops dramatically due to the large volume expansion and rapid and efficient exhausting vis-à-vis the high conductance pathway and the high vacuum pump. In addition, purge zones separating adjacent exhaust zones can be added to provide an additional isolation by forming a gas diffusion barrier between reactive gases without diluting or directly impacting the deposition zones. This is achieved by maintaining a flow of an inert gas in a continuous or preferably pulsed manner between adjacent exhaust zones and in the direction of the respective dedicated exhaust zones.

The use of dedicated deposition zones that are well separated provides many advantages. For example, cross-contamination is minimized and thus the substrates are readily available for the next gas injection as opposed to needing to wait for sufficient time to clear the previous precursor in the deposition volume with a purge gas, as is the case with the conventional system. In addition, the precursor exhaust paths are well separated so that CVD like deposition within the vacuum system, including in particular the vacuum pumps, is minimized, if not eliminated, resulting in long-lived pumps and lower cost of ownership.

The pulsing of precursor gases into the precursor inlet zones can be achieved using high speed valves that are timed appropriately with the rotation of a given substrate into a given deposition zone. One or more valves and/or one or more features, including slit like features, some of which may be curved like the substrate, may be employed in a given precursor inlet zone to adequately achieve the degree of uniformity of gas distribution across the substrate as required to get adequate uniformity of precursor deposition. Under some conditions, a simple inlet hole/port, as opposed to a slit, may be sufficient to introduce the precursor into the inlet zone.

The substrate holder and precursor regions may be maintained at different temperatures using various heating means and chamber materials. Typically for non-plasma assisted depositions, process temperatures would be in the range of 150° C. to 500° C. A plasma could be coupled to a given deposition zone to enhance the reactivity of a given precursor. The plasma may be of the direct or indirect type. For plasma assisted depositions, temperatures would typically be below 150° C. In another aspect of the invention, different precursor inlet zones are maintained at moderately different temperatures. In addition, higher order chemistries requiring more than two precursors can be accommodated. Also, exhaust zones could be independently temperature controlled. Thus, different aspects of the invention provide for a better ability to independently tune and control the deposition process.

In the preferred embodiment where a disk is used as a substrate holder, a hub structure may be included to serve as a barrier to direct the flow of precursors across the apparatus along the radial or near radial directions.

### BRIEF DESCRIPTION OF THE DRAWINGS

The invention has other advantages and features which will be more readily apparent from the following detailed description of the invention and the appended claims, when taken in conjunction with the accompanying drawings, in which:

FIG. 1 is a front perspective view of an ALD apparatus according to the invention.

FIG. 2 is an exploded tilted perspective view of the ALD apparatus of FIG. 1.

FIG. 3 is another exploded tilted perspective view of the ALD apparatus of FIG. 1.

FIG. 4 is a cross-sectional view showing a precursor region of the ALD apparatus of FIG. 1.

FIG. 5 is a cross-sectional view showing the rotational coupling of mechanical and electrical energy into the vacuum.

FIG. 6 is a block diagram of gas control system for controlling the ALD apparatus of FIG. 1.

FIG. 7 is a schematic showing an overview of a system using the ALD apparatus of FIG. 1.

FIG. 8 is a plan view of an alternative upper chamber part for an ALD apparatus.

FIG. 9 is a cross-sectional view of an apparatus depicting a mechanism for setting clearances.

FIG. 10 is a graph of thickness of an ALD-deposited layer as a function of number of cycles, from experiments using a prototype ALD apparatus.

FIG. 11 is a graph of non-uniformity in thickness of an ALD-deposited layer as a function of number of cycles, from experiments using a prototype ALD apparatus.

FIG. 12 is a top view of an alternative embodiment of an ALD apparatus using concentric cylinders with a vacuum annulus.

FIG. 13 is side view of the ALD apparatus of FIG. 12.

### DETAILED DESCRIPTION OF THE PREFERRED EMBODIMENTS

Before moving on to specific embodiments, a few comments about the conventional ALD process and apparatus are in order. A complete conventional cycle typically requires four steps to produce a monolayer. First, a first precursor gas is introduced into the reactor chamber and adsorbs onto a substrate. Second, the excess first precursor gas is then purged from the reactor chamber. Third, a second precursor gas is introduced into the reactor chamber and reacts with the first adsorbed precursor. Finally, the reaction by-products and the excess second precursor gas is purged from the reactor chamber leaving behind the desired layer on the substrate. This process is repeated to grow a layer of desired thickness. In fact, the first several cycles typically do not result in a uniform layer across the substrate as some substrate sites grow preferentially but eventually the surface is covered and growth continues across the entire surface. An important consideration is that the temperature of the chamber and substrate must fall in a range that is high enough for the chemistry to have sufficiently high reactivity but low enough that the first precursor does not desorb from the substrate surface. Also, the temperature must not be so high that the precursors disassociate or breakdown. This implies that there is a temperature window within which the ALD process works and that the reactor and substrate preferably should be controlled for the ALD process to work properly.

In addition, several other important considerations may come into play in designing ALD equipment and processes. First, if the first precursor gas remained in the chamber when the second precursor gas is introduced, CVD behavior would occur in the reaction chamber, resulting in a lower quality film. Second, the time required to purge the gas precursors from the reaction chamber can be significant, resulting in low cycle rates that contribute to low throughput. In addition, reaction on the chamber walls can result in film growth on the chamber walls that may later become a source of particles or degrade chamber performance, (e.g., heat transfer characteristics). As another factor, the chemical efficiency is typically very low such that only about one percent of the chemical precursors introduced into the reactor chamber are actually deposited onto the substrate. The majority of the precursors is exhausted by the vacuum pumping system and/or deposited on the chamber walls. Vacuum pump systems can quickly degrade and fail prematurely if significant CVD deposition occurs in the pump as is often the case with the reactive chemistries associated with ALD. Finally, proper control of temperature and/or plasma (reactivity) is important for process control and film quality.

One example of ALD chemistry is the deposition of aluminum oxide, Al2O3. Trimethyl-aluminum (TMA) and water (H2O) are commonly used as a first and second precursor, respectively, for the Al2O3 deposition. Water tends to strongly adsorb onto the reaction chamber. As a result, it is not easily exhausted and the purge time is lengthened, reducing the throughput of the ALD apparatus. If a high cycle rate is maintained, the residual water on the chamber surface and the subsequent TMA pulses deposit layers on the chamber walls and may also contribute to significant CVD film on the substrate. In addition, as the water is pumped out during the TMA cycle, Al2O3 deposits in the vacuum pump forming a hard layer that will prematurely wear out moving parts.

As another example, ammonia (NH3), which is mainly used as a second precursor gas to form a metallic nitride thin film, is easily adsorbed onto the reaction chamber and is not easily exhausted. If ammonia is not adequately removed from the reaction chamber, it can react with the precursor gas of the next cycle, generating particles and increasing the amount of impurities in the thin film.

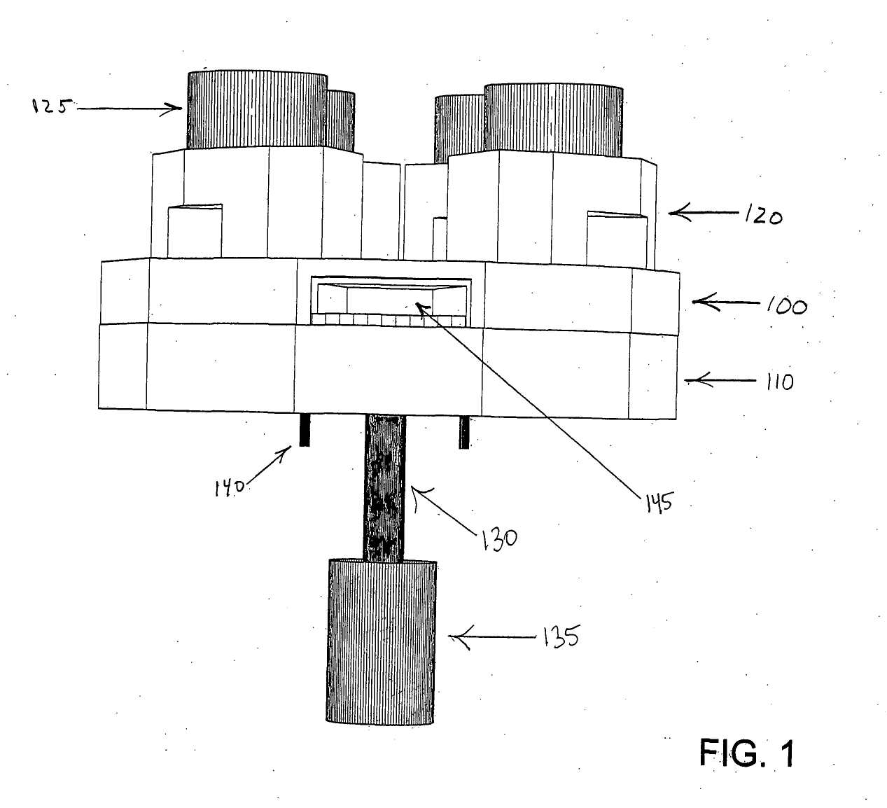

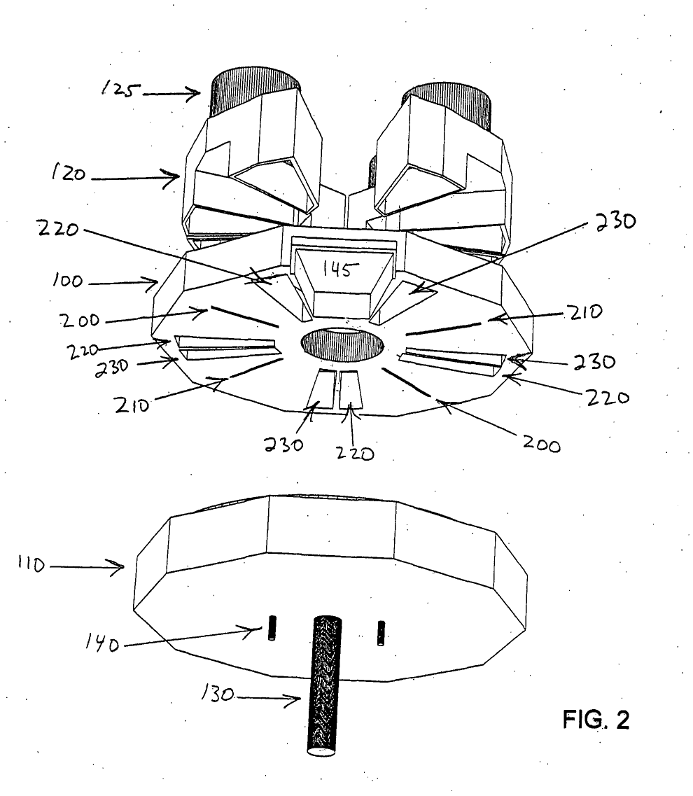

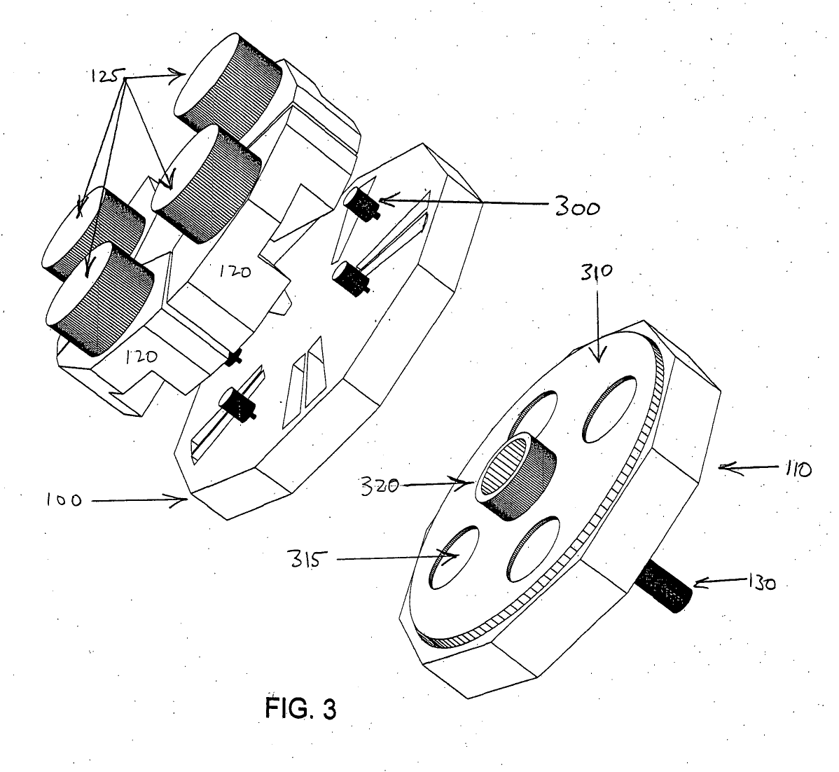

Turning now to the figures, FIG. 1 is a front perspective view of an example ALD apparatus according to the invention. FIG. 1 shows a chamber upper part 100 and a chamber lower part 110, as well as plenums 120 and high vacuum pumps 125. A drive shaft 130, drive motor 130, and optional backside purge ports 140, and load lock area 145 are also shown. FIG. 2 is an upwards looking exploded view that more clearly shows precursor inlet zones and the bounding exhaust zones. FIG. 3 is a downward looking exploded view that more clearly shows a substrate holder (disk) and the associated substrate recesses. Also shown are high speed valves for supplying the precursors to deposition zones. The ALD apparatus is divided into different precursor regions, four in the example of FIGS. 1-3.

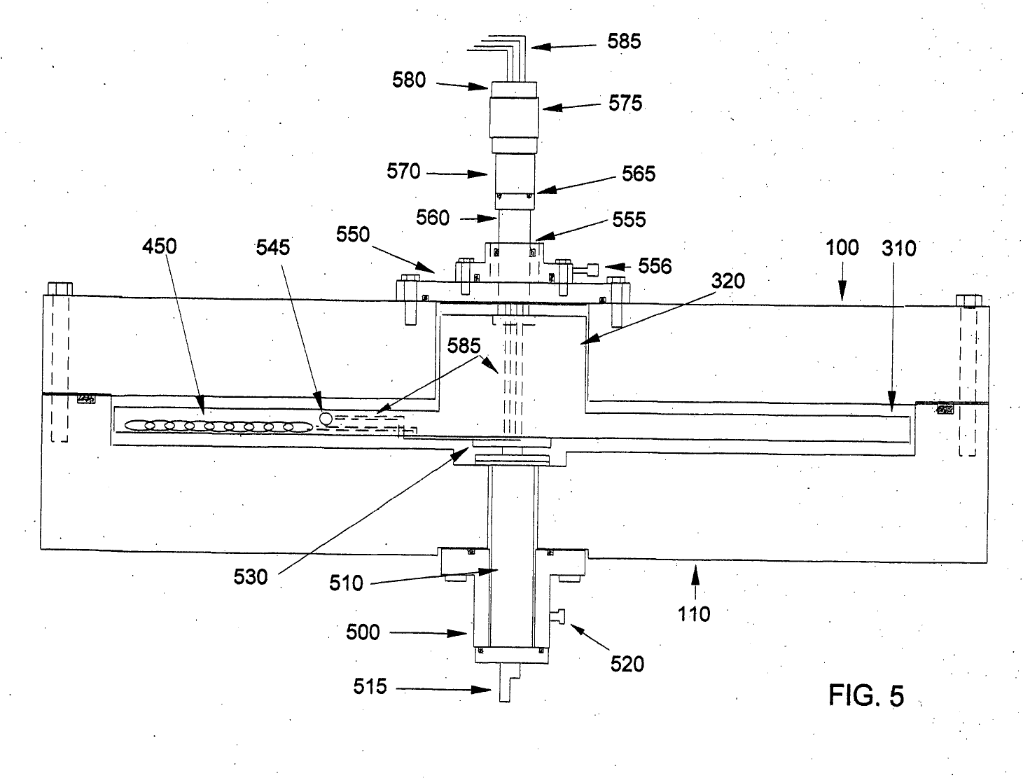

In this particular design, the chamber lower part 110 has a high precision bearing and ferro-fluid vacuum seal assembly (see FIG. 5) for supporting a substrate holder. The chamber lower part 110 and drive shaft 130 are coupled via the ferro-fluidic bearing and vacuum seal assembly. The motor 135 is coupled to the drive shaft 130 and is operated to index and rotate a substrate holding disk (not clearly seen in this view). The plenums 120 direct the exhaust from the different precursor regions into high vacuum pumps 125 which themselves are coupled to roughing pumps (not shown). In this way, the exhaust from a given precursor region is better directed into specific exhaust paths, reducing unwanted deposition on the walls of the chamber and exhaust system.

FIG. 2 shows the gas passageways of the apparatus. There are two precursor regions for a first precursor and two precursor regions for a second precursor. The two precursor regions for the first precursor include the first precursor inlet zones 200 and their corresponding exhaust zones 220. Similarly, the two precursor regions for the second precursor include the second precursor inlet zones 210 and their corresponding exhaust zones 230. Inlet zones 200 and exhaust zones 220 are part of one precursor region, and inlet zones 210 and exhaust zones 230 are part of the next precursor region. In an alternate embodiment, a purge inlet is provided between exhaust zones 220 and 230 of adjacent precursor regions to provide a gas curtain to minimize flow of precursors and reaction by-products between the exhaust zones 220 and 230.

The inlet zones 200, 210 preferably are small so as to minimize the volume of precursor injected. The exhaust zones 220, 230 preferably are large and provide a boundary to the inlet zones 200, 210 so as to provide good gas conductance and a “vacuum” reservoir. Essentially, an incoming gas pulse (injected from one of the inlet zones 200, 210) enters the corresponding exhaust zone 220, 230 such that the pressure stays low and the pumping speed and efficiency stays high. Preferably, there should be low to no overlap of precursor inlet zones and exhaust zones, meaning that as the substrate (recess) enters a given precursor inlet zone and gas is injected there is no longer any portion of the recess directly under an exhaust zone. If this is not the case, the gas pulse may too readily propagate to the exhaust zone. In some systems, some overlap may be advantageous to provide a “draw” on the gas along the substrate. The exhaust zones 200, 230 preferably are positioned to provide a boundary around the inlet zones 200, 210. For example, in FIG. 2, the exhaust zones 200, 230 bound the corresponding inlet zones 200, 210 both on the leading edge and on the trailing edge. That is, as the substrate rotates through the precursor regions, it first encounters one of the exhaust zones, then the inlet zone and then the other exhaust zone.

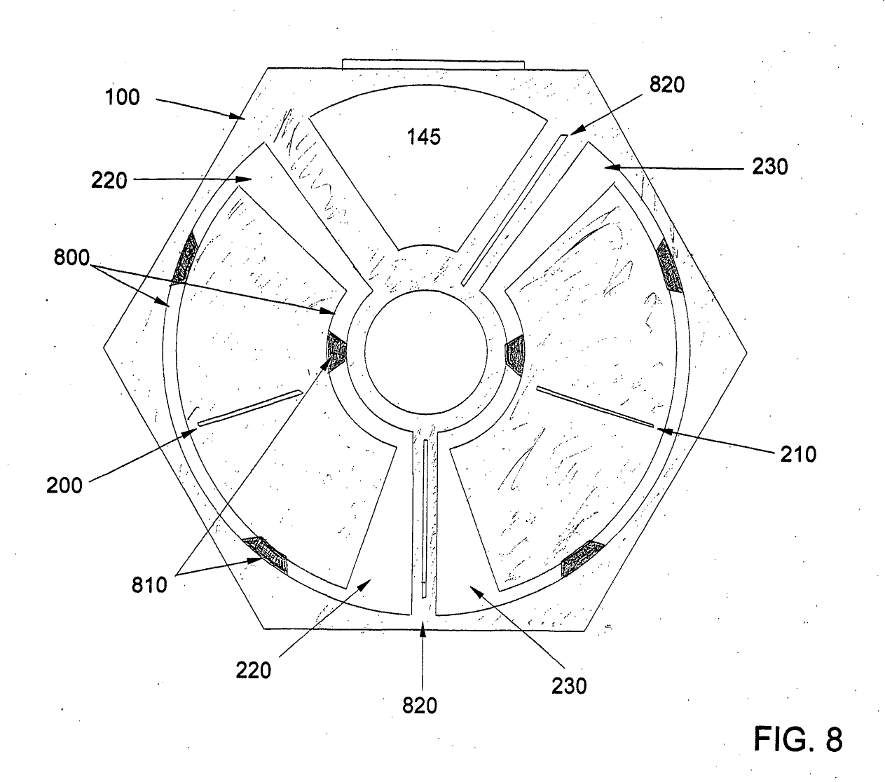

The shape of the inlet zones and exhaust zones may vary. For example, given the circular symmetry of wafers, it may be advantageous for the inlet zones 200, 210 to follow a curved trajectory which may provide for a more compact system and/or a better overall performing system. Also, the shape of the exhaust zones 220, 230 may also include a circuit connecting the paired exhaust zones so as to form a complete boundary surrounding the inlet zone, as is shown in FIG. 8.

FIG. 3 shows fast valves 300, substrate holder 310, the substrate recesses 315, and the disk hub 320. If needed, a means to secure the substrates such as edge clips can be provided as are well known in the art of semiconductor manufacturing (not shown). Other well known means such as an electrostatic chucking mechanism could also be implemented and is not shown. Typically, heat transfer requirements are adequately met by the conduction between the heated substrate holder and the substrate. If this is insufficient, a heat transfer coupling gas, like helium, could be employed on the back side of the wafer as is typically done with electrostatic chuck systems to provide adequate heat transfer, if needed.

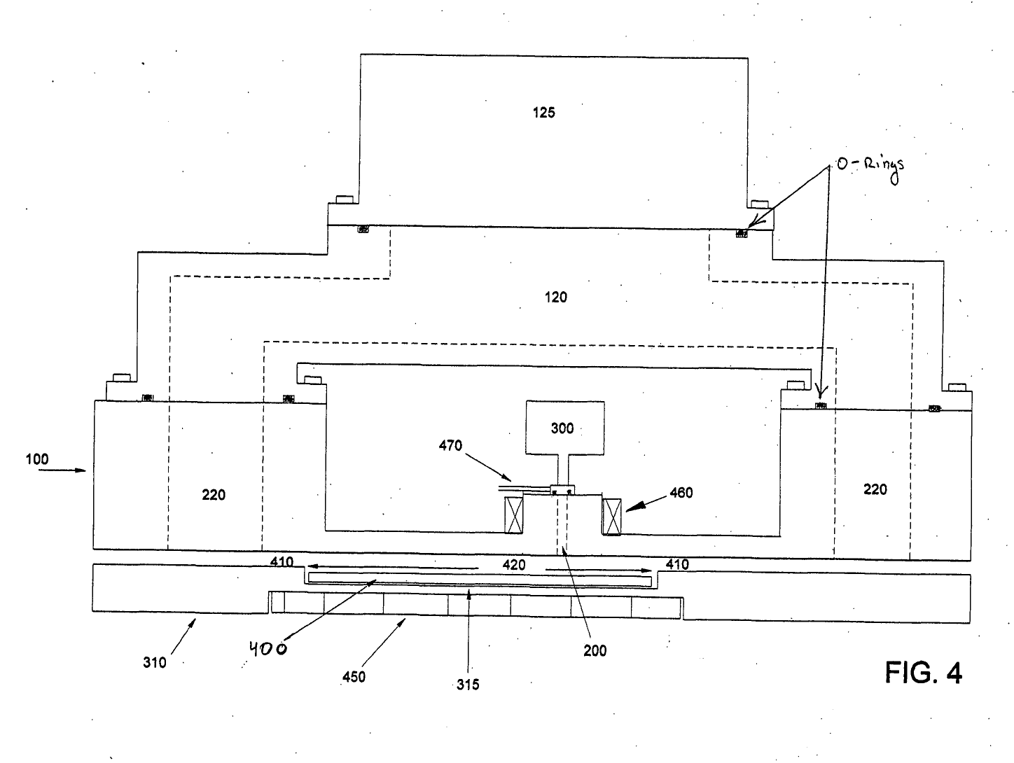

FIG. 4 shows that the chamber upper part 100 is composed of precursor inlet zones 200 that extend along a radial direction (into the page) and that are used to introduce precursor gases. The chamber upper part 100 and the rotating substrate holder 310 form relatively flat “gap regions” 410. These gap regions 410 limit the flow of precursors introduced by different deposition inlet zones 200. Along with recesses 315, they also serve to define a small volume deposition zone 420 adjacent to large volume exhaust zones 220. The exhaust zones 220 remove the excess precursor and serve to direct the flow along the gap so as to construct an effective deposition zone 420 within the gap space in around the precursor inlet zone 200. The height of the gap region 410 is preferably maintained at 0.100 inch to less than 0.005 inches to reduce the flow along the azimuthal and radial directions. More preferably the gap is 0.020 inches or smaller such that physical contact between the moving disk and upper chamber is avoided but that the distance separating the chamber face and the disk is minimized. Some consideration is also made for the relative thermal expansion of the constituent chamber components, which may close the gap 410 upon heating. Independent adjustment and control of the substrate holder 310 to upper chamber part 100 clearances may also be provided. The substrate 400 temperature is maintained using a heater 450 attached to the underside of the disk recess 315. Alternatively, the entire substrate holder could be heated with heating elements distributed accordingly. The temperature of the precursor inlet 200 is maintained using heaters 460. The incoming supply line 470 for valve 300 may also be heated using well known methods such as heat tape. Heaters and/or cooling lines could be directly coupled to the atmospheric side of the upper chamber 100 to control the temperature of regions of the chamber as needed.

FIG. 5 depicts the mechanical coupling assembly 500 for transmitting rotational energy and the electrical coupling assembly 550 for transmitting electrical signals to the rotating disk 310. The mechanical assembly 500 is mounted to the lower chamber 110 and contains a commercially available (e.g., from Rigaku Corp. of Tokyo, Japan or Ferro Tec Corporation, Nashua, N.H. USA) ferro-fluid seal and bearing assembly 510 with a mechanical shaft 515 that is coupled to the disk with a mounting 530. An optional purge port 520 is shown that may be used to provide a purge to help keep reactive gases away from the seal assembly. This purge gas may also provide thermal coupling between ferrofluid seal assembly 510 and the mechanical couple 500 to better control the temperature of the ferrofluid seal, which may be susceptible to failure at modest temperatures of ˜100° C.

The upper electrical coupling assembly 550 is composed of a hollow shaft ferro-fluid seal assembly 555 that is commercially available (e.g., from Rigaku Corp. of Tokyo, Japan or Ferro Tec Corporation, Nashua, N.H. USA) with a hollow conduit 560 mounted inside of it. The top of the conduit is connected with an o-ring to an epoxy electrical feed-through that passes the electrical signals on wires 585 from the vacuum into the atmosphere. The electrical signals are coupled from the feed-through on the atmosphere side to a rotating slip-ring or mercury contactor (Merco Tac Incorporated, Carlsbad, Calif.) assembly 575 that allows the signal wire to be connected to a non-rotating structure 580 for connection to power supplies, etc. In the vacuum, the wires 585 are run down the center of the system and then run out along the disk 310 where they are connected to the substrate heater 450 and thermocouple 545.

The operation of the ALD apparatus involves the introduction of a first precursor into a first precursor inlet zone 200 via a high speed valve(s) 300. This introduction may be as a single injected pulse or a plurality of injected pulses. The precursor gas so introduced flows through the adjacent gap regions 410 toward the exhaust zones 220 (precursor introduced by inlet zone 210 is exhausted by exhaust zones 230, and so on). As the disk 300 rotates, the substrate 400 (e.g., a silicon wafer) is exposed in one precursor region to one of the precursor gases that forms a monolayer on the substrate 400. The substrate 400 then passes through the exhaust zone 220 to remove the excess precursor before entering the next precursor region bounded by its own exhaust zones 230. The reason for using adjacent exhaust zones is to better maintain separation of the waste stream. The next adjacent precursor inlet zone 210 is injected with a second precursor gas and as the substrate 400 passes through the corresponding deposition zone 420, the second precursor reacts with the first precursor monolayer on the substrate 400 to form a first atomic layer. This process is repeated such that a film grows on the substrate layer by layer to a desired thickness. In this specific design, the rate of rotation of the substrate holder 320 is in the range of 30-1000+ rpm, although even lower rates of rotation would yield competitive results with many existing ALD tools, particularly if more than one pair of precursor regions was used.

Increasing the number of precursor regions means that multiple ALD cycles can be performed on each rotation. For example, if the ALD apparatus contained two precursor regions for each precursor, then a rotaton rate of 600 rpm would yield 20 ALD cycles per second. This appears to be an order magnitude improvement over the best ALD systems published to date. If necessary, the chemical rates of reaction could also be enhanced using plasma radical techniques in a given deposition zone so that the chemistry could be more compatible with the mechanical speed. Provided the chemistry is sufficiently fast and the distribution across the wafer is uniform, the system could, in principle, be run at 1000's of rpm. At 3000 rpm with two precursor regions for each precursor, a cycle rate of 100 cycles per second can be achieved. If this cycle is achievable with order 0.2 to 1 angstrom per cycle, the system would achieve a deposition rate of 20 to 100 angstroms per second, respectively. Within one minute, ALD layers with thicknesses of 1200 to 6000 angstroms (or 0.12 um to 0.6 μm) could be achievable. Even at 600 rpm, the system could achieve 240 to 1200 angstroms per minute, which would be a significant advance over current systems. Experimental results of a two precursor system of TMA and water operating at 240 rpm yielded 4 ALD cycles/sec at about 1 angstrom/cycle, resulting in an effective deposition rate of over 200 angstroms/min, which is a fast deposition rate compared to currently available production systems.

The fast valves 300, available from various vendors including Swagelok of Solon, Ohio USA and Fujikin of Osaka, Japan are used to pulse the precursor gas into the deposition zones 420 via the precursor inlet zones 200. Note that more than one fast valve 300 may be employed in a given deposition zone 420. This way, it is possible to have multiple pulses, which may be time delayed relative to each other, into the deposition zone 420 for a given substrate 400 pass. The use of multiple valves could alternatively be used to decrease the duty cycle on a given valve so as to decrease the maintenance cycle requirements. Another reason for using multiple valves is to provide adequate precursor gas as the current technology of these fast valves is limited to fairly low control volumes. The supply inlets for non-depositing gases (purges or plasma background gases) are not shown but these inlets could be coupled to the deposition zones 420, exhaust zones 220 and 230, and/or in between the exhaust zones 220 and 230.

Pulses of gas precursor diffuse from the small volume deposition zones 420 into the exhaust zones 220 and 230, which are substantially pumped by high vacuum pumps 125, such that this action contributes significantly to the reduction of cross-precursor contamination concentration in each of the respective deposition zones 420. In this way, a high concentration of precursor can exist in the deposition volume 420 for a brief period while the substrate is passing through the deposition zone 420 and yet very effective removal of precursor and reaction by-products is possible in the exhaust zones 220 and 230. Another important advantage is that because the deposition zones 420 are dedicated, there is no need to introduce a purge to prepare them for a different precursor. This means that there is no explicit purge requirement of the deposition zone 420 and there is a much lower propensity to build up deposited layers on the internal chamber upper part 100 walls. A purge could be employed between adjacent exhaust zones (e.g., between exhaust zone 220 and exhaust zone 230) to provide some background inert flow as well as serve as a gas curtain between adjacent precursor domains or regions.

The system is not meant to be internally leak proof but rather leak tolerant. The backside space below the disk may be purged using purge inlets 140 or constituted of a relatively large evacuated region such that deposition in this region may occur without degradation or interference in the upper space where the work piece substrate 400 is located. Any sealing mechanisms should not introduce or generate intolerable particle levels.

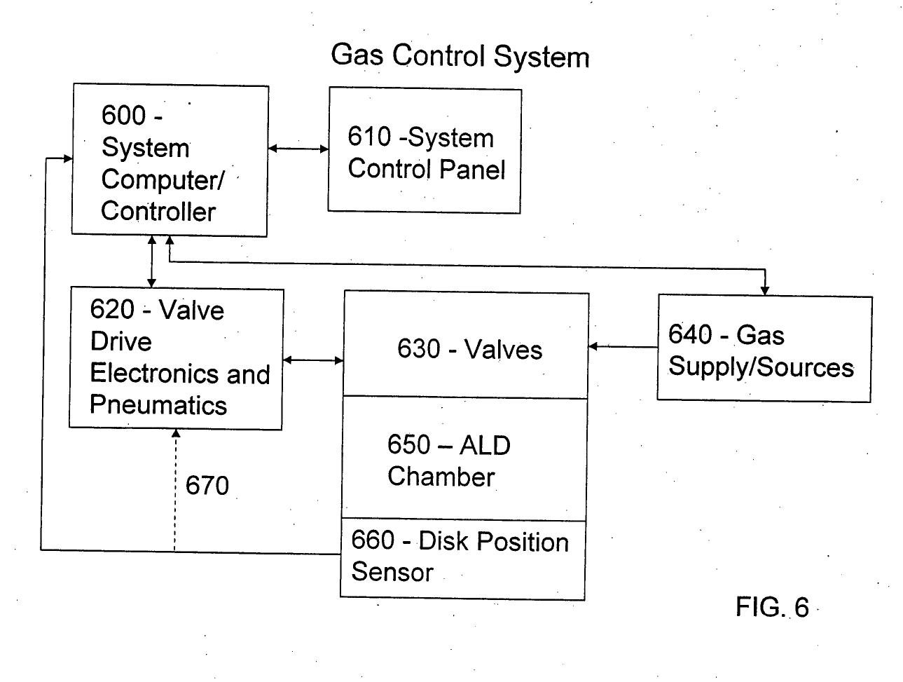

In FIG. 6, the system computer 600 is accessed by the control panel 610 and provides the user-interface to the overall system, including the gas control system. Once a recipe is created and saved, it can be run by the system control computer and/or a programmable logic controller (PLC) 600 that sends the appropriately timed signals to the valve drive electronics and pneumatics interface 620. The valve drive mechanisms 620 send the appropriate signals to the valves, high speed and standard speed valves 630 alike, to provide gases from the gas source supply system 640 to the ALD chamber 650 (as depicted in FIGS. 1-5). The timing of the valve signals is provided to the control system or directly to the valve drive interface (dashed line 670) via a disk position sensor 660 similar to ignition timing signals on an automobile, which can be advanced or retarded relative to the substrate position as needed to obtain proper gas distribution in a given precursor region.

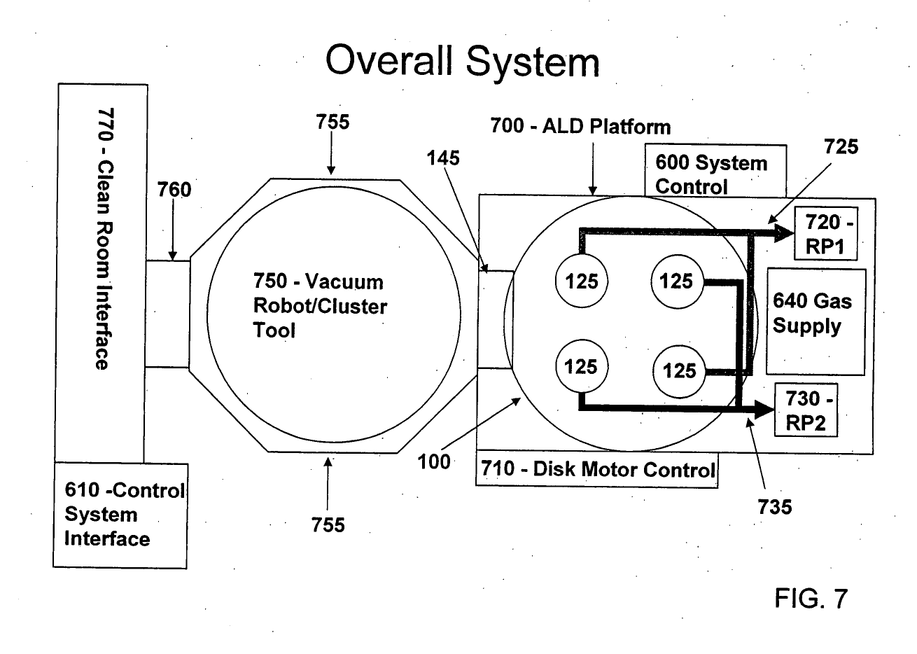

FIG. 7 depicts the overall system as it may appear in a semiconductor manufacturing factory. A few elements of the ALD apparatus shown in FIGS. 1-6 are depicted: two of the high vacuum pumps 125 corresponding to the first type of precursor exhaust zones 220, as discussed earlier, are connected to roughing pump RP1, and the other two high vacuum pumps corresponding to the second type of precursor exhaust zones 230 are connected to roughing pump RP2. A few of the subsystems are also shown, including the gas supply system 640, the disk motor control system 710, and the system control computer/PLC 600. The clean room interface 770 serves as the point of placement and retrieval of process substrates. It also typically includes an in air robot that serves to transfer substrates to a notch alignment tool and then into the load lock 760. The control of the entire system, including substrate movements, can be monitored and controlled at the control interface 610. After alignment, the substrates are transferred into the vacuum cluster tool 750 which moves substrates between the various process tools including the ALD platform 700 (such as shown in FIGS. 1-4) and other tools that could be located at the other ports 755 and are nested or clustered according to the needs of the process module. Note that the exhaust streams downstream of the high vacuum pumps could be joined to flow into one roughing pump if that roughing pump had sufficient ability to withstand the deposition process or if there were a vacuum trap placed in the vacuum foreline to remove excess deposition products prior to the roughing pump inlet.

As a variation to FIG. 7, the vacuum cluster tool 750 may be connected to more than one ALD platform 700. Each ALD platform 700 is dedicated to depositing a specific type of film. However, the central robot 750 can transfer the substrates between different ALD platforms, thus building up different combinations of films.

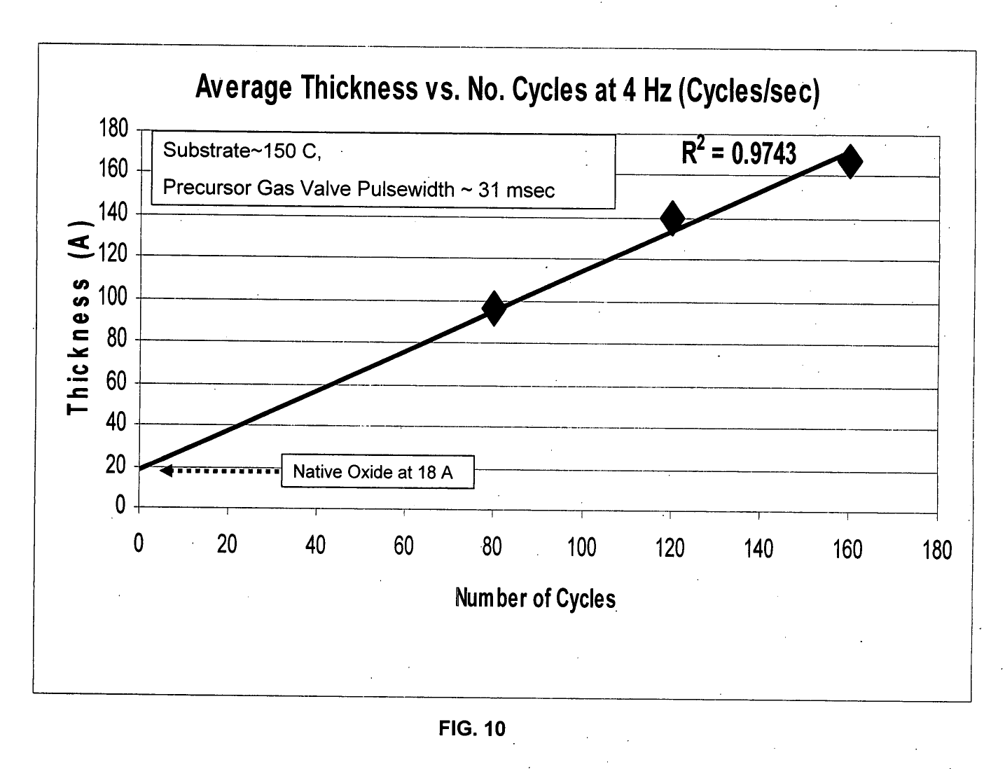

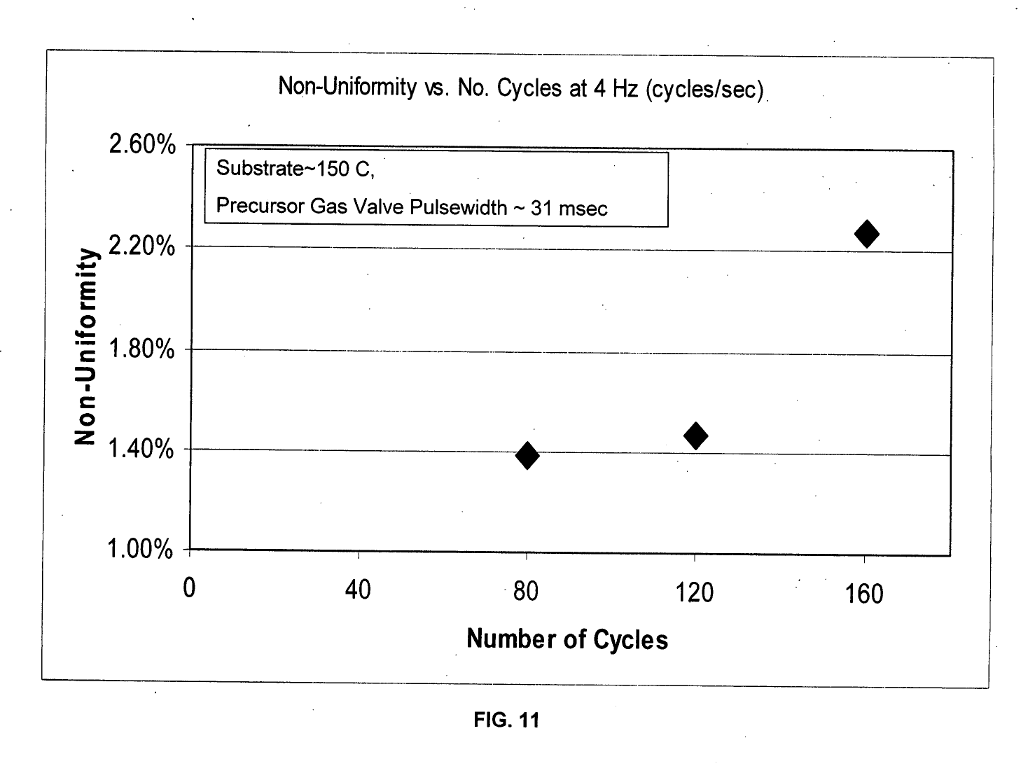

FIGS. 10-11 show data obtained from a prototype ALD system with two precursor zones. FIG. 10 plots layer thickness of deposited alumina as a function of the number of cycles. Experimental data were obtained for 80, 120 and 160 cycles. Good linearity with cycle number was observed, with a deposition rate of approximately one angstrom per cycle as expected for ALD behavior for this chemistry. FIG. 11 plots non-uniformity for the same experiments. Low non-uniformity was observed. In addition, chemical analysis by x-ray-photoelectron spectroscopy indicates that the films have low contamination and show good stoichiometry. The prototype system, although primitive in construction, was capable of achieving acceptable film quality at a deposition rate of (1 angstrom/cycle)×(4 cycles/second)=4 angstroms/second. This is already approximately 5-10 times faster than currently available production systems.

FIGS. 1-7 show one specific design. However, other implementations will be apparent. For example, in one embodiment, there are four exhaust plenums, two on either side of a first and second precursor inlet zone. Each exhaust plenum has its own turbo pump and for a given precursor region the corresponding turbo pumps are connected to the same dry pump so as to maintain separate waste stream paths for the precursors and their associated by-products. Obviously, the upper chamber and plenums could alternatively be made as one piece, instead of discrete components, if this is desired for manufacturing and/or process considerations.

An alternative embodiment involves using purges and/or exhaust in the intervening zones separating the precursor regions from each other in effect making a more tortuous path. The use of a purge alone usually would be unsatisfactory because of the dilution impact on the precursor gases. The use of a physical seal is generally not preferred due to the particulates generated and the potential for rapid fatigue.

The substrate holder should be large enough and dynamically balanced to hold at least one substrate such that it could be rotated through the series of exhaust zones. There would also be isolation or semi-isolation achieved along the radial and vertical aspects of the system by the chamber design and/or seals. One alternative embodiment is shown in FIG. 8 which shows a simple two precursor zone system with the common exhaust zones 220 and 230 being connected along inner and outer radii, thus forming a complete boundary surrounding the precursor inlet zone 200 and 210, respectively. Also shown are the additional internal chamber wall supports 810 that are recessed to allow vacuum conductance. Also shown are optional purge inlet zones 820. There could also be a purge zone on the inner radius just inside the exhaust zone inner radii. One other possibility is a tortuous path with purging/vacuum, similar to the axial system, to minimize radial cross chamber flow as well as vertical flow below the substrate holder.

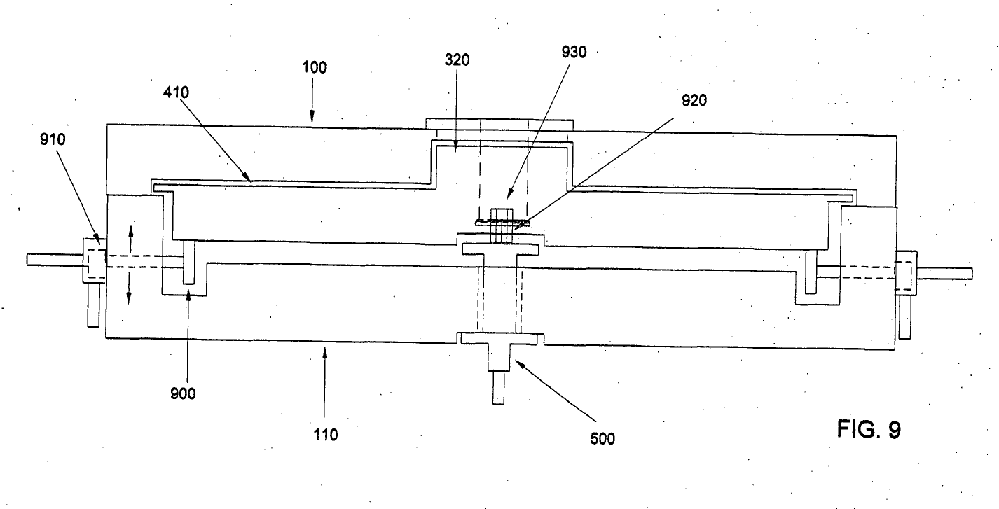

Another consideration is the relatively tight tolerances maintained between the inner chamber wall and the rotating disk. As depicted in FIG. 9, it may be advantageous to use a series of laterally mounted precision wheels mounted on sealed bearings 900 inside the lower chamber 110 that can be adjusted with a vernier 910 on the outside of the chamber to set the gap 410. This adjustment can be used using a dial indicator on the top surface of the disk before the upper chamber 100 is installed or with the upper chamber 100 installed it could be set using interferometric measurements made through a top chamber 100 view port. The disk 320 can move up and down along the center drive shaft spline 920 and after the height is set the disk can be secured using a set nut 930. Other methods of setting the clearance include using a simple shim on the center shaft disk mounting plate or using a vertical robot tool with a vacuum bellows. This shim approach is simple and reasonably robust.

Note that the substrate holder recess acts as a vacuum source when it is rotated into a given deposition zone such that a precursor is drawn toward the substrate surface. In other words, there is low residual pressure in the small recess volume above the substrate because it has been essentially exhausted. As a result when the substrate moves to the next precursor inlet zone, the next precursor gas readily propagates toward the substrate surface without excess interference from residual reaction by-product gas and/or purge gas. In one specific design, the recess depth is preferably maintained such that the substrate surface is within about 0.020″ of the disk face to just level or slightly above the disk face. For example, a substrate that is 0.020″ thick preferably would have a recess depth of between 0.020″ to 0.035″ such that the substrate face is just flush with the disk face or recessed by up to about 0.015″. A deeper recess results in a relatively larger volume for the deposition zone and therefore higher gas loading, which typically leads to lower performance and a less efficient system. A recess that is shallower than the substrate thickness means that the substrate surface would protrude above the disk face and the clearance between the disk and the upper chamber would be designed to take this protrusion into account. In general, it is desirable to maintain an effective recess gap above the substrate of less than 0.020″ to 0.001″, which results in a very small volume for the deposition zone as the wafer is moved into the inlet zone. The resulting deposition volume is typically a small fraction of the exhaust volume. Hence, the small precursor gas pulse is effective at covering the substrate because the relative concentration/pressure is high in the deposition volume (although still typically less than a torr) but drops quickly as the gas reaches the exhaust zone. Additional recesses, not necessarily circular, could be added between the substrate recesses on the substrate holder and would act as “scoopers” for removing residuals from the deposition zones.

The deposition zones could be isolated in the chamber upper part so as to have independent heating and/or cooling elements that could provide independent temperature control of the precursor chemistry and perhaps cold traps in the exhaust zones. Each region could also have an inlet port(s), exhaust port(s), and/or measurement port(s).

The means for achieving rotation of the substrate holder within the chamber may by direct mechanical means or an inductive means. Use of an inductive means may substantially improve sealing issues because only a feed-through wire(s) would be needed as opposed to a mechanical axle and wire feed-through. However, a direct mechanical coupling with a rotating vacuum seal is a more standard approach. Also, some mechanism is provided to lift the substrates from the recesses so that the vacuum robot may place and retrieve them from the disk. This is typically achieved with lift pins that are connected to a vertical robot mechanism via vacuum bellows. When the substrate is positioned in the load lock area, the lift pins move up through the disk via small through-holes and lift the substrate to a height where the cluster tool vacuum robot may access the bottom of the substrate.

In an alternate embodiment, the geometry could be linear rather than circular. In the circular geometry of FIGS. 1-9, deposition zones were the results of substrates rotating past inlet zones. In a linear geometry, a linear reciprocating substrate holder could traverse a linear series of inlet zones, thus forming a linear series of deposition zones. However, a rotating system has an advantage of mechanical ease, reliability, and throughput.

The diffusion process at working pressures of ˜1 mT to ˜1 Torr in the deposition zone is fast so that viscous flow dynamics play only a minor role in distributing each precursor across the substrate. The flow behavior is perhaps best described as transitional or Knudsen flow. The diffusion or movement of the precursor pulse(s) across the deposition zone and into the exhaust zones is rapid and serves several purposes. First, it distributes the precursor across the substrate with a relatively high concentration. Second, the pressure/concentration drops the farther the pulse propagates toward and into the exhaust zone such that the pumps can operate at an efficient vacuum pressure, i.e., operate in their high throughput regime. Excess precursor gases are exhausted from the exhaust zones primarily by transitional and/or molecular flow.

Preferably, the exhaust plenum volumes are 10-1000 times or more as large as the deposition zone volume so that a pressure of order 1 Torr in the deposition volume would equate to 1 mT to 100 mT in the exhaust zone. Typically, high vacuum turbomolecular pumps operate in their high throughput regime at pressures below about 100 mT. Note that a given pulse volume of precursor gas into the deposition zone may result in the outflow of a much larger volume of gas at an equivalent pressure (or a higher pressure at the same volume) because of the chemical reactions that may take place. For example, the TMA molecule contains three methyl groups which are liberated in the reaction with water such that for every molecule of TMA reacted, three molecules of methane gas (CH₄) are liberated which essentially increases the pressure by a factor of three. At higher pressures and flows, larger pumps would be needed to maintain a comparable pumping capability and as pressures increase, the risk of particle movement increases. Conversely, it may be advantageous for improving film quality to use higher capacity pumps to keep the exhaust plenum pressures below 10 mT or so. In general, this is readily achievable and is a tradeoff in terms of pump cost, required flows, and required film quality.

The relative leak when traversing from a given precursor inlet zone at a higher pressure to the adjacent lower pressure exhaust zone provides a flow path across the wafer of the precursor that essentially extends the effective deposition zone beyond the slit into the gap. A simple analysis of diffusion of the pulse of gas into the gap shows that moderately high levels of precursor are present in the gap on a timescale that is consistent with the time that the wafer is present in the precursor region as it is rotating. This has several benefits. The required precursor volume is generally low compared to prior art approaches. In addition, the amount of precursor required per cycle is low, resulting in a more efficient and cleaner system. In fact, commercially available flow restrictor orifices (e.g., from Lenox Laser, Glen Arm, Md., USA) may be used in some cases where the precursor pressure is relatively high to restrict the flow through the valves and/or conduit. Alternatively, needle valves may serve a similar purpose or with adjustments of the valve Cv with the adjustment screw as is available on the Swagelok of Solon, Ohio USA ALD valves.

It is readily possible to operate at higher pressures such that viscous flow may be dominant in the precursor inlet zone and into the gap. Under these conditions, the use of a showerhead may be advantageous to distribute the precursor across the precursor inlet zone and/or the deposition zone. In this case, the high speed valves potentially could be replaced with slower more standard valves operated in a more continuous manner. This embodiment may be advantageous when some CVD contribution to the thin film is acceptable. Industry demands are currently forcing some ALD tool suppliers to operate in the near CVD regime in order to achieve desired throughputs.

Another consideration is the generation of particles in semiconductor process equipment. With this consideration in mind, flaking of deposited layers on chamber walls or from the substrate holder should be minimized. Through the use of separated regions containing only one precursor or purge/exhaust, the deposition on the walls should be reduced if not eliminated, which will increase the interval between maintenance cycles as well as reduce particle generation sources. On the other hand, the substrate holder traverses the different precursor regions along with the substrates. In one solution, the substrate holder is a maintenance item or could be made with or coated by a material that does not have an affinity for either precursor for a given deposition chemistry. Finally, given the low working pressures, particulate movement resulting from flow displacement typically will not readily occur.

One other consideration is that the separation of precursor regions allows for different temperatures for each precursor, perhaps to enhance reactivity, which is an advantage not realized in other systems. Another advantage of this system is that the exhaust from one type of precursor region(s) can be connected to separate vacuum pumps from the other precursor regions so that deposition in the exhaust system is minimized or eliminated. This is a great benefit with respect to cost of ownership because vacuum pumps will last longer.

In another embodiment, the high vacuum pumps could be omitted and replaced with a more direct coupling to roughing pumps. This would be the case if the deposition process did not require high vacuums to achieve the desired results. Typically, this would be more of a CVD operation rather than ALD.

In another embodiment, plasma or radical sources could be coupled to the deposition zones to increase the reaction rates of the chemistry. One such radical source is the surfatron microwave plasma source. One approach to couple the plasma source would be to provide an access port on the side of the upper chamber 100 along an inlet zone (200 and/or 210).

In another embodiment, the traditional two-precursor system is adapted to provide a coupling means to introduce catalysts, plasma-sustaining gases or intermediaries in common or separated deposition zones. This consideration could also apply to more complicated chemistries such that additional precursors zones are included, i.e., precursor 1-N zones.

In another embodiment, the substrate holder could be inclined with respect to the rotational axis so that the wafers could be held in place on the rotating disk, if necessary, via the centrifugal force and with edge clips. This force may also provide for better conductive contact with the disk for better temperature control.

Conductive heat transfer in a relative vacuum is generally poor because typically there are few points of direct contact between surfaces so under high vacuum conditions it may be desirable to introduce some gas flow on the backside of the substrate to enhance the heat transfer between the disk recess and the substrate. Another means of securing the substrate to the disk is the use of electrostatic chucks. This would complicate the disk system but this may be required to accomplish adequate temperature control of the substrate.

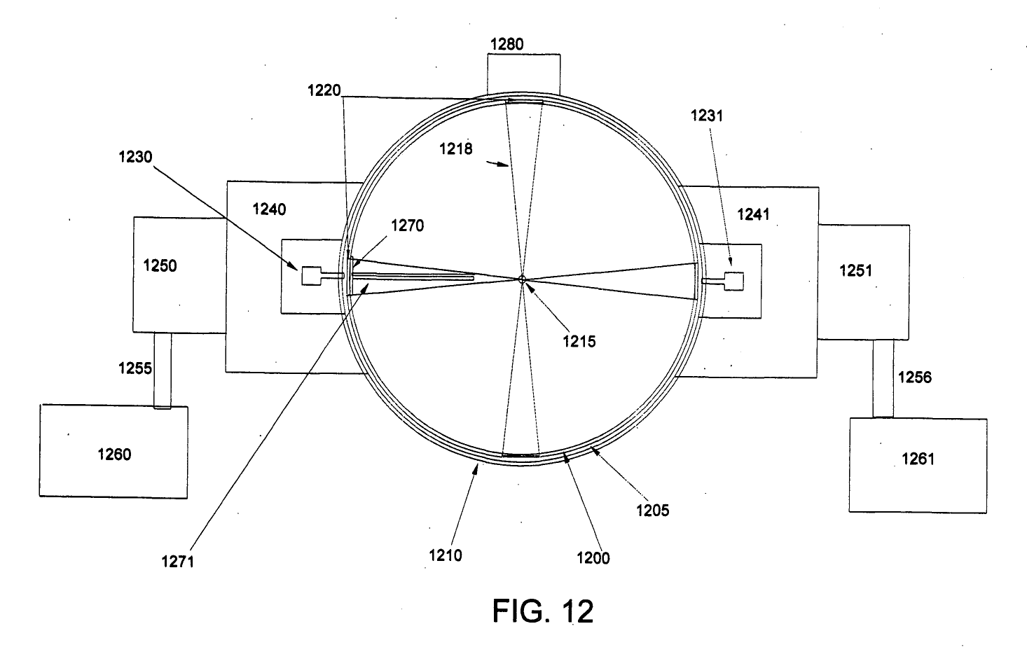

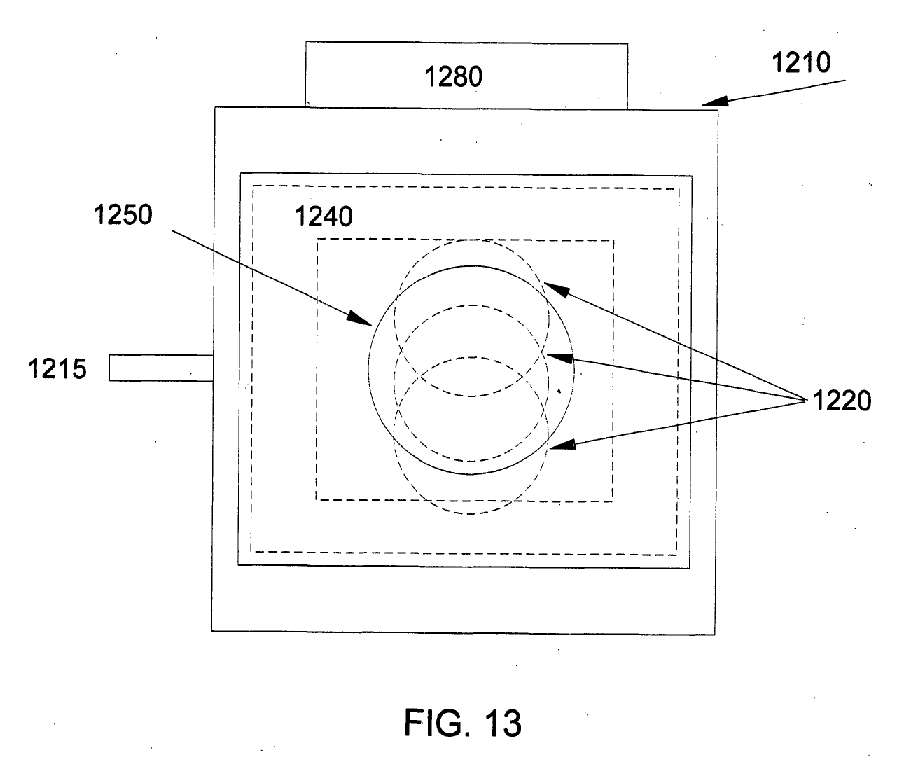

FIGS. 12 and 13 show a design in which the ALD apparatus includes two concentric cylinders 1200, 1210 with a vacuum region 1205 in between. FIG. 13 is a view from the right side of FIG. 12. Substrate holders 1220 are located on the outer diameter of the inner cylinder 1200. The inner cylinder rotates and the outer cylinder remains stationary, in this way the substrates cycle through the different precursor regions. The inner cylinder is supported by axis 1215, for example composed of a ferrofluid assembly to couple mechanical and electrical power to the cylinder and into the vacuum to heat and regulate heaters 1270 via conduits 1218. The outer cylinder has exhaust regions 1240, 1241 and precursor inlet zones with valves 1230, 1231, as well as a load lock 1280. FIG. 13 shows the substrate 1220 in three different locations as it rotates through one of the precursor regions.

This design uses the principle of separated gas pathways for a given precursor with a dedicated exhaust plenum/high conductance pathway 1240 (1241), high vacuum pump 1250 (1251), foreline 1255 (1256), and roughing pump 1260 (1261). The precursors are pulsed into the lower volume inlet zone by valves 1230 (1231). The deposition zones typically will have a slightly larger volume compared to the geometry of FIGS. 1-9, due to the requirement of rotating the flat wafer face along a curved trajectory. However, if a non-planar surface, such as a lens, was the substrate then smaller deposition volumes would be achievable. This embodiment also uses the principle shown in FIG. 8, whereby the entire deposition zone is surrounded by a dedicated exhaust zone 1240, as shown in FIG. 13.

In this embodiment, a load lock 1280 could be located at the top or the side depending on the orientation of the barrel (vertical or horizontal) and once again clearances between the inner and outer chamber forming the vacuum annulus region 1205 would be tight to reduce cross-flow between different precursor regions.

In an alternate approach, the substrates are mounted to the inner radius of the outer cylinder 1210, which would then be rotated with the valves and plenums being mounted to the inside of the inner chamber wall which would now be stationary. This approach may be more preferable in that the substrates are well supported and less prone to break by the centrifugal force but this approach also makes the load lock more difficult.

In both approaches, the end caps are also designed to reduce cross-flow. In one implementation, a flat circular plate is welded or bolted with a seal to the end of each barrel (one is static and other rotates) such that there is a small clearance between the end caps. Ferrofluid rotating seals are mounted on one (or both ends if needed) of the barrel and allows for the relative motion of the two barrels with respect to one another on a smaller axial radius 1215.

As another example, the ALD apparati described above can also be designed to include a measurement window(s) or other monitoring devices. Optical measurements, such as optical pyrometry, ellipsometry or laser transmission, may be made through the measurement window. For example, a laser may be transmitted through a measurement window, to a control deposition, and then exiting the chamber through the same or a different measurement window. The exiting laser beam may be incident onto a photodetector to measure the thickness of the growing layer. This assembly can be used as an in-situ process control tool.

Different chemistries can also be used with the ALD apparati described above. For example, in binary systems, two precursors are used. As one example, the first precursor may be selected from an organometallic compound of Al, Cu, Hf, Ir, La, Pt, Pa, Rh, Ru, Sr, Ta, Ti, W, Y, Zn, or Zr, such as trimethlyaluminum, cyclepentadienylcopper, pentakis(dimethylamino)tantalum, etc., or an inorganic compound of these elements such as a halide, nitride, oxide, or sulfide, for example copper chloride or ruthenium tetroxide. The second precursor for oxidation or reduction of the corresponding first precursor may be selected from O*, O2, O3, H*, H2, NH3, N*, H2O, OH*, air, or a combination of any of the above with an inert and/or noble gas where the asterisk corresponds to radical or plasma enhanced elements.

Systems using more than two precursors can be based on the binary systems described above, for example a more complex chemistry layer involving more than two chemical precursors, e.g., a HfSiON compound or a LaSrCuO compound. Another class involves the formation of nano-laminate layers in disjointed binary or tertiary sequences. A layer of one type is grown for several angstroms using one binary or tertiary sequence followed by another type of layer grown by a binary or tertiary sequence in a repeated A-B or A-B-C, etc., pattern forming a nano-laminate composed of a stacked sequence of thin layers.

Although the detailed description contains many specifics, these should not be construed as limiting the scope of the invention but merely as illustrating different examples and aspects of the invention. It should be appreciated that the scope of the invention includes other embodiments not discussed in detail above. Therefore, the scope of the invention should be determined by the appended claims and their legal equivalents.

What is claimed is:

1. An ALD apparatus comprising:
a chamber part having two or more precursor regions, each precursor region having one or more inlet zones bounded by one or more exhaust zones;
a substrate holder located in close proximity to the chamber part for cyclically moving substrates through the precursor regions, wherein movement of a substrate past the inlet zones of a precursor region forms a deposition zone for the precursor region; and deposition zones for adjacent precursor regions are separated by a gap formed between the chamber part and the substrate holder, the gap having a lower gas conductance than the exhaust zones; and
wherein, for each precursor region: the inlet zones are for injecting a precursor gas into the deposition zone, the exhaust zones are for exhausting excess precursor gas and/or reaction by-products from the deposition zone, the exhaust zones have a higher gas conductance than the deposition zone, and the gap and the exhaust zones are positioned to limit cross-flow of the precursor gas to other precursor regions.

2. The ALD apparatus of claim 1 wherein the excess precursor gas and/or reaction by-products are exhausted from the exhaust zones primarily by transitional and/or molecular flow.

3. The ALD apparatus of claim 1 wherein the inlet zones for adjacent precursor regions are sufficiently separated so that any substrate cannot simultaneously form deposition zones for adjacent precursor regions.

4. The ALD apparatus of claim 1 wherein the precursor regions are positioned in a linear array and the substrate holder moves the substrates in a linear motion.

5. The ALD apparatus of claim 1 wherein the precursor regions are positioned in a circular array and the substrate holder moves the substrates in a circular motion.

6. The ALD apparatus of claim 5 wherein the substrate holder holds the substrates in a single plane.

7. The ALD apparatus of claim 5 wherein the substrate holder holds the substrates along a periphery of a cylinder.

8. The ALD apparatus of claim 1 further comprising:
exhaust pathways coupled to the exhaust zones, wherein different precursor gases are exhausted via separate exhaust pathways.

9. The ALD apparatus of claim 1 wherein the ALD apparatus does not include any purge inlet zones.

10. The ALD apparatus of claim 1 further comprising:
purge inlet zones positioned between adjacent precursor regions.

11. The ALD apparatus of claim 1 wherein each precursor region is dedicated to a single precursor gas.

12. The ALD apparatus of claim 1 further comprising:
valves coupled to the inlet zones for pulsed injection of the precursor gases.

13. The ALD apparatus of claim 1 wherein, for each precursor region, the exhaust zones form a complete boundary surrounding the inlet zones.

14. An ALD apparatus comprising:
a chamber part having two or more precursor regions arranged in a circular array about a central axis, each precursor region having one or more inlet zones bounded by one or more exhaust zones;
a rotatable substrate holder located in close proximity to the chamber part, wherein rotation of the substrate holder cyclically moves substrates through the precursor regions, movement of a substrate past the inlet zones of a precursor region forms a deposition zone for the precursor region, and deposition zones for adjacent precursor regions are separated by a gap formed between the chamber part and the substrate holder, the gap having a lower gas conductance than the exhaust zones; and
wherein, for each precursor region: the inlet zones are for injecting a precursor gas into the deposition zone, the exhaust zones are for exhausting excess precursor gas and/or reaction by-products from the deposition zone, the exhaust zones have a higher gas conductance than the deposition zone, and the gap and the exhaust zones are positioned to limit cross-flow of the precursor gas to other precursor regions.

15. The ALD apparatus of claim 14 wherein the excess precursor gas and/or reaction by-products are exhausted from the deposition zones into the exhaust zones primarily by transitional and/or molecular flow.

16. The ALD apparatus of claim 14 wherein the inlet zones for adjacent precursor regions are sufficiently separated so that any substrate cannot simultaneously form deposition zones for adjacent precursor regions.

17. The ALD apparatus of claim 14 further comprising:
exhaust pathways coupled to the exhaust zones, wherein different precursor gases are exhausted via separate exhaust pathways.

18. The ALD apparatus of claim 14 wherein each precursor region is dedicated to a single precursor gas.

19. The ALD apparatus of claim 14 wherein the inlet zones and exhaust zones extend along a radial direction.

20. The ALD apparatus of claim 19 wherein the exhaust zones are wider than the inlet zones along a tangential direction.

21. The ALD apparatus of claim 14 further comprising:
valves coupled to the inlet zones for pulsed injection of the precursor gases.

22. The ALD apparatus of claim 14 wherein, for each precursor region, the exhaust zones form a complete boundary surrounding the inlet zones.

23. The ALD apparatus of claim 14 further comprising:
for at least one precursor region, at least one valve for injecting a gas having at least two constituent gases.

24. The ALD apparatus of claim 23 wherein the constituent gases include a precursor gas and a catalyst.

25. The ALD apparatus of claim 23 wherein the constituent gases include a precursor gas and a plasma sustaining gas.

26. The ALD apparatus of claim 14 further comprising:
for at least one precursor region, at least two valves for injecting gases to the deposition zone.

27. The ALD apparatus of claim 26 wherein at least two of the valves inject a same gas on alternating cycles of the substrate through the precursor region.

28. The ALD apparatus of claim 26 wherein at least two of the valves inject a same gas on a same cycle of the substrate through the precursor region.

29. The ALD apparatus of claim 26 wherein at least one of the valves injects the precursor gas and at least another one of the valves injects a catalyst gas.

30. The ALD apparatus of claim 26 wherein at least one of the valves injects the precursor gas and at least another one of the valves injects a plasma sustaining gas.

31. The ALD apparatus of claim 14 further comprising:
for at least one precursor region, at least one valve for injecting a gas to continuously sustain a plasma in the precursor region.

32. The ALD apparatus of claim 14 wherein the ALD apparatus does not include any purge inlet zones.

33. The ALD apparatus of claim 14 further comprising:
purge inlet zones positioned between adjacent precursor regions.

34. The ALD apparatus of claim 14 wherein the gap is less than approximately 0.100 inches.

35. The ALD apparatus of claim 14 wherein the gap is less than approximately 0.020 inches.

36. The ALD apparatus of claim 14 wherein the gap is less than approximately 0.005 inches.

37. The ALD apparatus of claim 14 wherein a recess gap between the chamber part and a surface of the substrate is less than approximately 0.020 inches.

38. The ALD apparatus of claim 14 wherein a recess gap between the chamber part and a surface of the substrate is between 0.001 and 0.020 inches.

39. The ALD apparatus of claim 14 wherein the substrate holder has recesses to receive substrates.

40. The ALD apparatus of claim 39 wherein the recesses provide an evacuated volume for drawing the precursor gas from the inlet zone towards the substrate.

41. The ALD apparatus of claim 14 further comprising:
a hub for limiting cross-flow of precursor gases along a radial direction.

42. The ALD apparatus of claim 14 wherein the substrate holder rotates at a speed of between 0.5 to 3000 rpm.

43. The ALD apparatus of claim 14 wherein the substrate holder rotates at a speed of between 30 to 1000 rpm.

44. The ALD apparatus of claim 14 wherein the substrate holder rotates at a speed sufficient to complete between 0.25 and 1000 ALD cycles per second.

45. The ALD apparatus of claim 14 wherein the substrate holder rotates at a speed sufficient to complete between 1 and 100 ALD cycles per second.

46. The ALD apparatus of claim 14 wherein the substrate holder rotates at a speed sufficient to complete between 1 and 10 ALD cycles per second.

47. The ALD apparatus of claim 14 wherein the ALD apparatus completes one ALD cycle per rotation of the substrate holder.

48. The ALD apparatus of claim 14 wherein the ALD apparatus completes two or more ALD cycles per rotation of the substrate holder.

49. The ALD apparatus of claim 14 wherein the substrate holder rotates at a speed sufficient to achieve a deposition rate of between 10 and 10,000 angstroms per minute.

50. The ALD apparatus of claim 14 wherein the substrate holder rotates at a speed sufficient to achieve a deposition rate of between 50 and 1000 angstroms per minute.

51. The ALD apparatus of claim 14 further comprising:
heaters for maintaining different precursor regions at different temperatures.

52. The ALD apparatus of claim 14 wherein the precursor regions are dedicated to at least three different precursor gases.

53. The ALD apparatus of claim 14 wherein the substrate holder has recesses between the substrates for removing residuals from the deposition zones.

54. The ALD apparatus of claim 14 further comprising:
at least one load lock area for loading and unloading the substrate holder.

55. The ALD apparatus of claim 14 wherein at least one of the precursor gases is plasma enhanced.

56. The ALD apparatus of claim 14 further comprising:
shims for adjusting the gap.

57. The ALD apparatus of claim 14 further comprising:
edge verniers for adjusting the gap.

58. The ALD apparatus of claim 14 further comprising:
an optical interferometric device for monitoring the gap.

59. The ALD apparatus of claim 14 further comprising:
a mechanical device for monitoring and/or adjusting the gap.

60. The ALD apparatus of claim 14 further comprising:
a measurement window to facilitate measurement of ALD deposition by the ALD apparatus.

61. The ALD apparatus of claim 14 wherein the inlet zones inject the precursor gas in a pulse with adequate pressure and flow to achieve monolayer saturation of the substrate surface as the substrate moves past the inlet zones.

62. A method for ALD deposition of a substrate comprising:
moving a substrate through at least two precursor regions wherein, during the movement through each precursor region:
forming a deposition zone as a result of movement of the substrate past one or more inlet zones;
injecting a precursor gas from the inlet zones into the deposition zone;
exhausting excess precursor gas and/or reaction by-products from the deposition zone via one or more exhaust zones that bound the inlet zones and have a higher gas conductance than the deposition zone; and
limiting cross-flow of the precursor gas to other precursor regions by placement of the exhaust zones and of a gap around the deposition zone; and
cyclically repeating the step of moving a substrate through at least two precursor regions.
